(19) United States
(12) Patent Application Publication
(10) Pub. No.: US 2017/0047223 A1
(43) Pub. Date: Feb. 16, 2017

(54) EPITAXIAL GROWTH OF GALLIUM ARSENIDE ON SILICON USING A GRAPHENE BUFFER LAYER

(71) Applicants: THE REGENTS OF THE UNIVERSITY OF CALIFORNIA, Oakland, CA (US); KING ABDULAZIZ CITY FOR SCIENCE AND TECHNOLOGY, Riyadh (SA)

(72) Inventors: Kang L. Wang, Santa Monica, CA (US); Yazeed Alaskar, Los Angeles, CA (US)

(73) Assignees: THE REGENTS OF THE UNIVERSITY OF CALIFORNIA, Oakland, CA (US); KING ABDULAZIZ CITY FOR SCIENCE AND TECHNOLOGY, Riyadh (SA)

(21) Appl. No.: 15/235,924

(22) Filed: Aug. 12, 2016

Related U.S. Application Data
(60) Provisional application No. 62/204,513, filed on Aug. 13, 2015.

(51) Int. Cl. H01L 21/02; H01L 29/04; H01L 29/20

(52) U.S. Cl. CPC H01L 21/02485; H01L 21/02381; H01L 21/02422; H01L 21/02389; H01L 21/0242; H01L 21/02444; H01L 21/02488; H01L 21/02546; H01L 21/02543; H01L 21/02549; H01L 21/0254; H01L 21/02609; H01L 21/02057; H01L 29/20; H01L 29/045

(57) ABSTRACT

Epitaxial growth of gallium arsenide (GaAs) on a semiconductor material (e.g., Si) using quasi-van der Waals Epitaxy (QvdWE). Prior to GaAs growth a buffer layer (e.g., graphene) is deposited which relieves lattice mismatch/thermal expansion. The low energy of the graphene surface and the GaAs/graphene interface is overcome through an optimized growth technique to obtain an atomically smooth low-temperature GaAs nucleation layer. The disclosure can be applied to optimize epitaxial thin film growth of other materials, (e.g., III-V semiconductors, such as InP, GaSb) on Si using van der Waals buffer layers such as graphene.

### CROSS-REFERENCE TO RELATED APPLICATIONS

This application claims priority to, and the benefit of, U.S. provisional patent application Ser. No. 62/204,513 filed on Aug. 13, 2015, incorporated herein by reference in its entirety.

### STATEMENT REGARDING FEDERALLY SPONSORED RESEARCH OR DEVELOPMENT

Not Applicable

### INCORPORATION-BY-REFERENCE OF COMPUTER PROGRAM APPENDIX

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND

1. Technical Field

The technology of this disclosure pertains generally to growing GaAs on semiconductor substrates, and more particularly to growing GaAs on thin films of graphene.

2. Background Discussion

Integration of III-V (Group III-V on the periodic table) compound semiconductors on silicon (Si) has been the focus of significant interest over the past 30 years. Compared to Si, most group III-V materials have higher carrier mobility, thus making them suitable candidates for high-speed electronic devices. Yet, due to its cost-effectiveness, chemical stability, and its high mechanical strength, Si is still considered the best choice for large-scale integration of microelectronic circuits. However, III-V materials have direct bandgaps, which is essential for efficient optoelectronic devices, such as light emitting diodes, lasers and photodetectors. Therefore, the integration of III-V materials with Si microelectronics is a burgeoning field with the goal of achieving high speed and efficient optical devices that can be fabricated at a significant performance and cost advantage using standard semiconductor fabrication techniques.

Among several integration methods, direct growth by heteroepitaxy is frequently used to produce the layered structures, which in turn are used for device fabrication. Several growth methods such as Molecular beam epitaxy (MBE), Metal Organic Chemical Vapor Deposition (MOCVD), and Chemical Vapor Deposition (CVD) have proven to be a useful tool to grow epifilms with atomically flat surfaces and abrupt interfaces. While nearly perfect homoepitaxial growth was demonstrated by MBE, heteroepitaxial growth is challenged by dissimilar chemical bonding, surface dangling bonds, surface states, and surface symmetry mismatch. In addition, lattice mismatch, polar-on-non-polar epitaxy, and thermal expansion mismatch add complexity to the direct heteroepitaxial growth of GaAs/Si. In this disclosure, we propose a method that can overcome such problems. This technique employs layered two-dimensional materials as a buffer layer that is self-passivated and inert, indicating a weak vdW interaction between the overlaid-3D-semiconductor and the 2D-layer.

Since the first demonstration in the 1980s on 2D/2D, such as selenium/tellurium and NbSe₂/MoS₂ material systems, van der Waals epitaxy (vdWE) has shown itself to be a useful route to heteroepitaxy, alleviating most of the aforementioned constraints.

A number of industry studies have been undertaken to achieve high-quality MBE-grown GaAs nanowires (NWs) on a graphene/Si substrate. A mixture of zincblende and wurtzite segments with twins and stacking faults were observed at the bottom of the NWs, whereas the rest of the NW is nearly a defect-free zincblende phase.

Additional studies have also demonstrated high-density, vertical, coaxially heterostructured InAs/InxGa1-xAs NWs, over a wide tunable ternary compositional range, through a seed-free vdWE approach using metal organic chemical vapor deposition (MOCVD) on graphene. Nevertheless, successful operation of NW-based devices is impeded by carrier loss mechanisms, surface-state induced band bending, Fermi level pinning, poor ohmic contacts, and uncontrolled incorporation of n- and p-type dopants. Poor optoelectronic performance due to the aforementioned issues prevents NW-based devices from superseding thin-film based ones.

A number of experimental investigations have been reported for the growth of GaAs/Si using layered GaSe. Unfortunately, significant success has not yet been reported for this approach due to the smoothness of the van der Waals buffer layer, the stacking faults in the grown GaAs and high defect density. Further reports on GaAs/GaSe system has not been reported.

Accordingly, a need exists for advanced techniques for employing van der Waals growth of GaAs on silicon, toward overcoming the smoothness problems, while providing additional benefits over previous techniques.

### BRIEF SUMMARY

Van der Waals growth of GaAs on silicon using a two-dimensional layered material, graphene, as a lattice mismatch/thermal expansion coefficient mismatch relieving buffer layer is presented. Two-dimensional growth of GaAs thin films on graphene is a potential route towards heteroepitaxial integration of GaAs on silicon in the developing field of silicon photonics. Hetero-layered GaAs is deposited by molecular beam epitaxy (MBE) on graphene/silicon at growth temperatures of 350° C. under a constant arsenic flux. Samples are characterized by plan-view scanning electron microscopy, atomic force microscopy, Raman microscopy and x-ray diffraction. The low energy of the graphene surface and the GaAs/graphene interface is overcome through an optimized growth technique to obtain an atomically smooth low-temperature GaAs nucleation layer.

In this disclosure, we present the first example of an ultrasmooth morphology for GaAs films with a strong (111) oriented fiber-texture on graphene/silicon using quasi van der Waals epitaxy, making it a remarkable step towards an eventual demonstration of the epitaxial growth of GaAs by this approach for heterogeneous integration. This disclosure is a step toward achieving high-quality single crystal GaAs that takes advantage of vdW epitaxy using graphene. The results described in this disclosure can be used to optimize epitaxial thin film growth of other III-V semiconductors, e.g., InP, GaSb on Si using van der Waals buffer layers such as graphene.

Further aspects of the technology described herein will be brought out in the following portions of the specification, wherein the detailed description is for the purpose of fully disclosing preferred embodiments of the technology without placing limitations thereon.

### BRIEF DESCRIPTION OF THE SEVERAL VIEWS OF THE DRAWING(S)

The technology described herein will be more fully understood by reference to the following drawings which are for illustrative purposes only:

FIG. 1A is a view of atomic geometry of a GaAs/multi-layer graphene/Si interface showing only the topmost graphene layer strained by heteroepitaxial growth, according to an embodiment of the present disclosure.

FIG. 1B is a layering schematic for a structure with GaAs grown on top of single layer graphene buffer layer/Si substrate, according to an embodiment of the present disclosure.

FIG. 2 is a layering structure of quasi van der Waals epitaxy of III/V semiconductor on van der Waals material layered on any arbitrary substrate, as utilized according to an embodiment of the present disclosure.

FIG. 3A through FIG. 3D illustrate properties of multi-layer graphene (MLG) flakes, with an image of mechanical exfoliation in FIG. 3A, an optical microscope image in FIG. 3B, a Raman spectrum in FIG. 3C, and an atomic force microscopy (AFM) image in FIG. 3D of a magnified area in FIG. 3B, as utilized according to an embodiment of the present disclosure.

FIG. 4 is a Raman Spectrum of CVD graphene transferred into Si/SiO₂ substrate, utilized according to an embodiment of the present disclosure.

FIG. 5A through FIG. 5D are schematic cross-section views and scanning electron micrograph (SEM) plan-view images of the surface of As-terminated GaAs grown on multi-layer graphene/Si with V/III ratios of 25 (FIG. 5A and FIG. 5B) and 10 (FIG. 5C and FIG. 5D) showing island growth and the formation of 1D nanorods, respectively, according to an embodiment of the present disclosure.

FIG. 6A through FIG. 6D are views of the as-grown graphene structure with V/III ratios of 25 and at a growth rate of 0.25 Å/s (FIG. 6A), 0.15 Å/s (FIG. 6B), with schematic cross-sectional view of the GaAs grown with Ga-prelayer on multi-layer graphene/Si (FIG. 6C), and atomic force microscopy (AFM) image (FIG. 6D) of the region marked in FIG. 6B showing surface morphology of the nucleation layer, utilized according to an embodiment of the present disclosure.

FIG. 7A through FIG. 7B are plots of room-temperature micro-Raman spectrum (FIG. 7A) for the low-temperature-grown GaAs nucleation layer, and the XRD omega rocking-curve scan of GaAs(111) peak for such nucleation layer (FIG. 7B), according to an embodiment of the present disclosure.

### DETAILED DESCRIPTION

### 1. Introduction

Van der Waals epitaxy (vdWE) has been proven to be a useful route to heteroepitaxy. Utilizing vdWE, depositing a material with three-dimensional (3D) bonding on a two-dimensional (2D) layered van-der-Waals material could be a new and interesting approach of heteroepitaxy. The bonds between the 2D material/upper 3D epilayer in this approach are about two orders of magnitude weaker in comparison to the covalent bonds between the 3D substrate/3D deposited layer. Therefore, the weak bonds between 2D/3D could accommodate thermal mismatch with different substrate temperatures during the growth. Furthermore, the strain due to the in-plane lattice-mismatch with the epitaxially-grown 3D overlayers is mitigated in quasi-van der Waals Epitaxy (QvdWE) due to low growth-axis bond energies. Considering further, the dislocations at the interface are not expected to propagate through the grown material due to the weak interactions at 2D/3D heterointerface. Only the topmost layer of the substrate with 2D nature is expected to undergo a change of its lattice parameters to be isomorphic with the epilayers grown on top due to the van der Waals forces between the layers of the substrate.

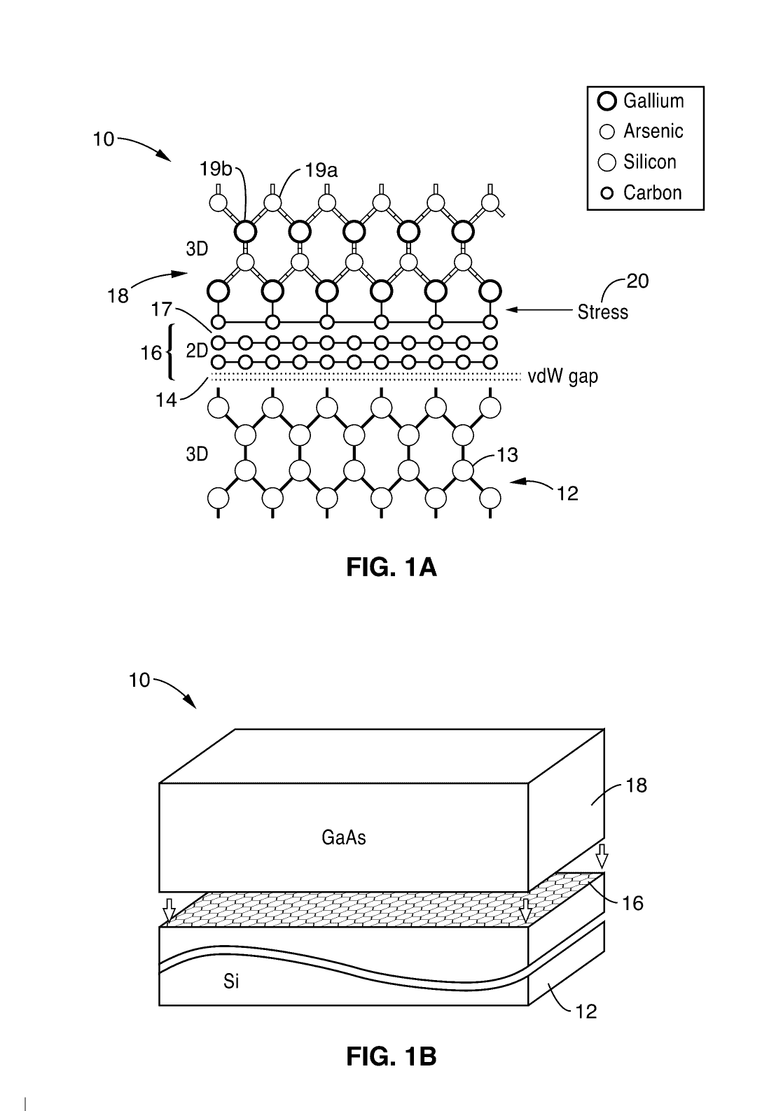

FIG. 1A illustrates an example embodiment 10 of depositing a material with three-dimensional (3D) bonding on a two-dimensional (2D) layered van-der-Waals material. The figure shows a portion of an Si (3D Si lattice) substrate 12 having Si atoms 13, showing vdW gap 14, and a 2D graphene layer 16 with its carbon atoms 17, upon which a 3D layer of GaAs 18 is seen with Arsenic 19a, and Gallium 19b atoms. Although stress 20 induced by the interaction between the grown 3D layer and 2D substrate may result in a non-ideal interface, the QvdWE is expected to lead to improved crystalline properties and reduced structural defects such as dangling bonds and dislocations in the grown overlayers.

This disclosed QvdW epitaxial growth of GaAs on Si using 2D materials acts as a buffer layer. Among other vdW materials, graphene is a thermally-stable material that has a high-decomposition temperature, thus making it an ideal material of choice as a buffer layer.

FIG. 1B illustrates an embodiment 10 of an approach using graphene as a buffer layer to facilitate growth of high-quality GaAs/Si films. A portion of an Si substrate 12 is seen upon which is deposited a graphene layer 16, and over which is formed a GaAs layer 18.

The atomically flat surface of graphene interacts with the deposited epilayer via van der Waals forces. This reduces the influence of the physical parameters of graphene when forming overlayer nuclei. Given the abundance of high-quality graphene and facile ex-situ transfer to almost any substrate surface, the constraint of twofold epitaxy required for other 2D materials, such as GaSe is circumvented. Furthermore, graphene is a promising substrate for flexible and transparent device applications, due to its excellent optical transparency and electrical conductivity.

Using modern fabrication, graphene can be produced by many different methods and combinations thereof. The exfoliated graphene method first used to produce graphene also created the highest quality graphene to date, at 200,000 cm²/(V s).

Chemical vapor deposition (CVD) has opened a new path for large-scale production of high-quality graphene films. The ability to grow high-quality GaAs films on Si or any polymeric substrates using graphene buffer layers, can provide a novel, low-cost, transparent and flexible electrode for a number of potential applications such as solar cells, light emitting diodes, or novel heterostructures. In this method, a copper foil or layer of other transition metals (for example, Cu, Ni, Pt or alloy) as a catalyst is heated in a chamber up to 1,000° C., exposing it to methane, and letting the graphene form on the metal surface. The process for CVD has been refined to about 30,000 cm²/(V s), but over the course of nine hours and burning consistently at high temperatures. A new method uses only a small amount of methane gas, which splits into hydrogen and carbon when it reacts with the copper. A nitrogen compound is added to smooth the copper's surface, making it easier for high-quality graphene to form there. Heat is provided via plasma burning at about 420° C. The graphene films are then transferred to any arbitrary substrates such as glass and polymers by etching away the metal. Other processes to grow graphene include room temperature CVD.

Recently a new manufacturing technique allowed growing graphene in a roll-to-roll process using a small vacuum chamber into which a vapor containing carbon reacts on a horizontal substrate, such as a copper foil. The new system uses similar vapor chemistry, but the chamber is in the form of two concentric tubes, one inside the other, and the substrate is a thin ribbon of copper that slides smoothly over the inner tube. This growth model is compatible with flexible substrates and our III/V van der Waals epitaxy on layered materials as proposed in this disclosure.

Epitaxial graphene can be grown on silicon carbide (SiC) substrates. Epitaxial graphene can be easily grown by heating the SiC single crystal in a high vacuum or in an inert gas atmosphere.

In this disclosure, experimental methods and their corresponding results are described, including microstructural characterization of the as-grown GaAs layer. The disclosed III-V/2D/Si system principle can be easily expanded to the growth of III/V compounds such as InAs, InP, InGaAs, GaSb, InGaSb and II/VI compounds. Furthermore, van der Waals material is not limited to graphene but can be expanded to other layered materials such as, Boron Nitride (BN), Indium Selenide (In₂Se₃), Tungsten Selenide (WSe₂), Molybdenum Selenide (MoS₂), Gallium Selenide (GaSe) and other van der Waals materials.

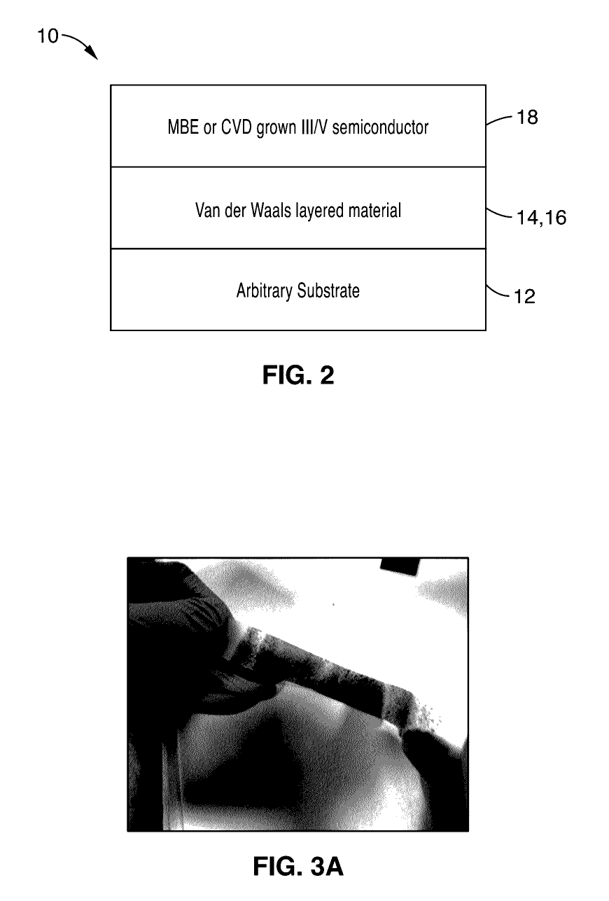

FIG. 2 illustrates an example embodiment of growth of various compounds, such as III/V semiconductor material. The figure depicts an arbitrary substrate 12, over which is a vdW gap 14 associated with van der Waals layered material 16, such as the described graphene, and upon which semiconductor 18 (e.g., III/V) or other materials 18, such as including II/VI materials 18 are shown. These materials may be grown on the van der Waals layer using any applicable process, such as including molecular beam epitaxy (MBE) or chemical-vapor deposition (CVD).

### 2. Surface Energy

The surface energy values calculated for single layer and bilayer pristine graphene along with 3D materials collected from the literature are listed in Table 1. The value for the surface energy of graphene is in agreement with prior experimental reports on the surface energy of graphene.

Although graphene atoms have dangling bonds only at the edges and defect sites, ideal graphene is a dangling-bond-free material, which results in both the surface energy of graphene and the interface energy between the grown film and the substrate to be negligible. Hence, the growth morphology of the deposited layers can be primarily predicted by the surface energy of only GaAs. Therefore, Bauer's surface energy formula for layer-by-layer growth can be simplified as

Δγ=γ_{GaAs}≦0 (2)

where Δγ is the relative magnitude of the free energy and γ_{GaAs} is the GaAs-vacuum interface energy. 2D materials, such as graphene and Bi₂Se₃, in general, have much lower surface energy compared to 3D materials as can be seen in Table 1. With Ga- and As-prelayer on graphene, the modified σ is calculated to be 0.43 J m⁻² and 0.57 J m⁻², respectively. The predicted order of magnitude increase in the surface energy of the Ga- (or As-) prelayer/graphene substrate compared to single and bilayer graphene suggests that this increases the wettability of the underlying graphene substrate, thus promoting the likelihood of layer-by-layer epitaxial growth occurring.

### 3. Experimental Procedure

The following process is described by way of example and not limitation. Multi-layer graphene (MLG) flakes were used as a vdWE buffer layer, and GaAs was deposited on MLG/Si (111) substrates using a Perkin-Elmer 430 MBE system. Material characterization was performed using a field-emission scanning electron microscope, atomic force microscope in the tapping mode and a double axis x-ray diffractometer with monochromatic CuKα (λ=1.5405 Å) radiation source. Raman spectra of MLG surfaces and as-grown GaAs films were collected at room temperature (RT) by using a Renishaw Raman microscope with a 514 nm excitation laser.

3.1 Sample Preparation

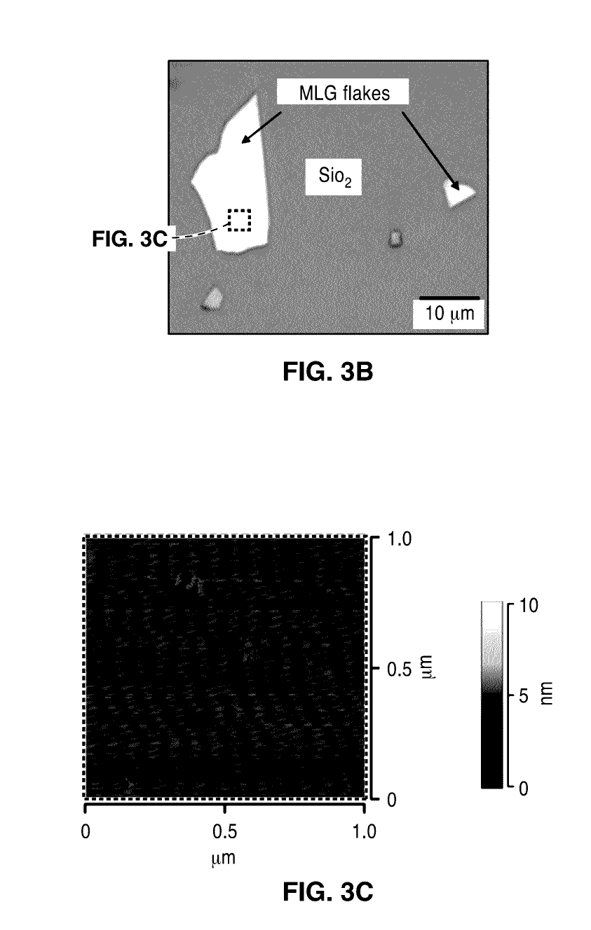

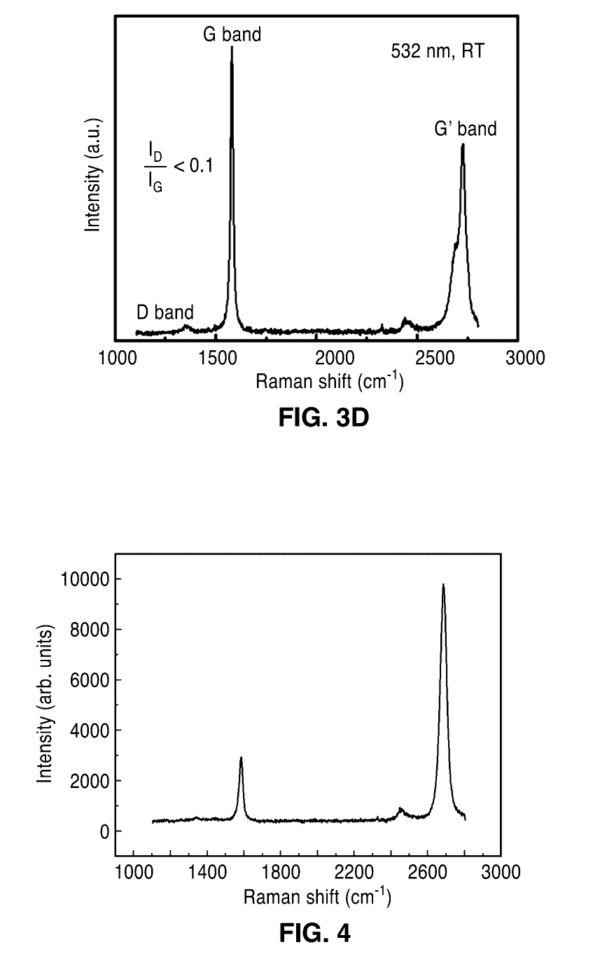

FIG. 3A through FIG. 3D illustrate aspects of an example for graphene processing. A 1 cm×1 cm section of Si was first rinsed in a cleaner, such as a non-polar solvent (e.g., acetone and isopropanol (IPA)) for five minutes. Then, graphene flakes were mechanically exfoliated onto non-HF-treated Si by the well-known adhesive-tape technique (i.e., “scotch-tape technique”) as seen in FIG. 3A. Finally the Si substrate with MLG was again cleaned using acetone and IPA to remove any residual organics from the exfoliation process. FIG. 3B depicts the corresponding microscope image of MLG flakes onto crystalline Si substrate covered with native SiO₂. FIG. 3C depicts the corresponding AFM image for the same MLG flake. Other graphene samples were prepared using CVD methods where the graphene is grown on Copper foil under methane gas at high temperatures in a chamber. After growth, the graphene is transferred onto the SiO₂ substrate, although it should be appreciated that any desired (arbitrary) substrate can be utilized.

3.2 Graphene Quality

Prior to GaAs growth, it is important to evaluate the quality of the exfoliated MLG layers and the CVD graphene. This was performed by characterizing the crystallinity and surface morphology of MLG flakes using Raman spectroscopy and AFM, respectively. FIG. 3D depicts a Raman spectrum of exfoliated MLG flakes on Si, showing the main features, which are the D, G and G′ bands. Among these bands, the main peaks are the so-called G and disorder-induced D peaks, which lie at 1580 and 1348 cm⁻¹, respectively. The integrated intensity ratio I_{D}/I_{G} for the D band and G band is less than 0.1, indicating the production of high-quality multi-layer graphene. The layers exhibit an atomically smooth surface morphology with a peak-to-peak variation of around 0.6 nm and a root-mean-square (RMS) roughness of 0.2 nm.

FIG. 4 illustrates a plot of Raman spectrum which indicates that a high quality single layer graphene with low defect density has been produced.

### 4. Experimental Results

To achieve high quality epitaxial growth, the nucleation step plays a significant role and influences the film properties, morphology, homogeneity, defect densities, and adhesion. Although the influence of the substrate on nucleation behavior is well understood from conventional nucleation theory, there is a limited understanding on the impact of the substrate on the nucleation layer growth in QvdWE using a buffer layer. To develop a detailed understanding of the nucleation and growth behavior of GaAs on Si via QvdWE, GaAs films were grown on MLG using As- or Ga-prelayer, and two-step growth. These grown layers were studied using a combination of SEM, AFM and XRD in order to optimize film quality. Prior to presenting the results, a short description on the preparation for each set of growth conditions will be provided.

4.1 GaAs Growth on As-Terminated MLG Surface

The acetone-IPA-cleaned exfoliated-MLG/Si samples were degassed at 300° C. for 10 min in the buffer tube of our MBE system prior to loading into the growth chamber. The sample was exposed to As flux, with a beam-equivalent pressure (BEP) of approximately 1×10⁻⁶ Torr. While exposed to the As flux, the substrate temperature was ramped to 400° C. to initiate growth by concurrent introduction of Ga at a nominal growth rate of 0.25 Å/s. After the growth of 25 nm GaAs, the Ga shutter was closed and the substrate was cooled down below 150° C. in the presence of the As flux before unloading. It should be appreciated that the above temperatures, times and specific equipment are provided herein by way of example only, and not by way of limitation on practice of the disclosed process.

From a thermodynamic point of view, it is expected that GaAs on MLG/Si system would follow an island mode growth caused mainly by the low surface energy of graphene. An As-terminated graphene surface will lead to approximately an order-of-magnitude larger surface energy of the graphene surface upon sticking. However, due to their low adsorption energy (i.e., large bond distance) on graphene, As atoms are not found to stick to the graphene surface at high temperatures. Moreover, due to the chemical inertness of the graphene surface, the migration energy of both Ga and As atoms are low at high temperatures. Thus, the diffusion length of Ga and As atoms is expected to be very high. Taking this into account, the deposition for the GaAs nucleation layer was performed at temperatures as low as 400° C. to reduce the diffusion length of incident atoms on the graphene. It should be noted that optimal temperature for GaAs growth is in the range of approximately 580° C. to 600° C.

Unfortunately, even this reduced growth temperature fails to prevent the clustering of GaAs into islands atop graphene mainly because of the low migration energy of Ga and As atoms on graphene. This leads to a poor-quality GaAs film due to island growth in the early stage of nucleation process.

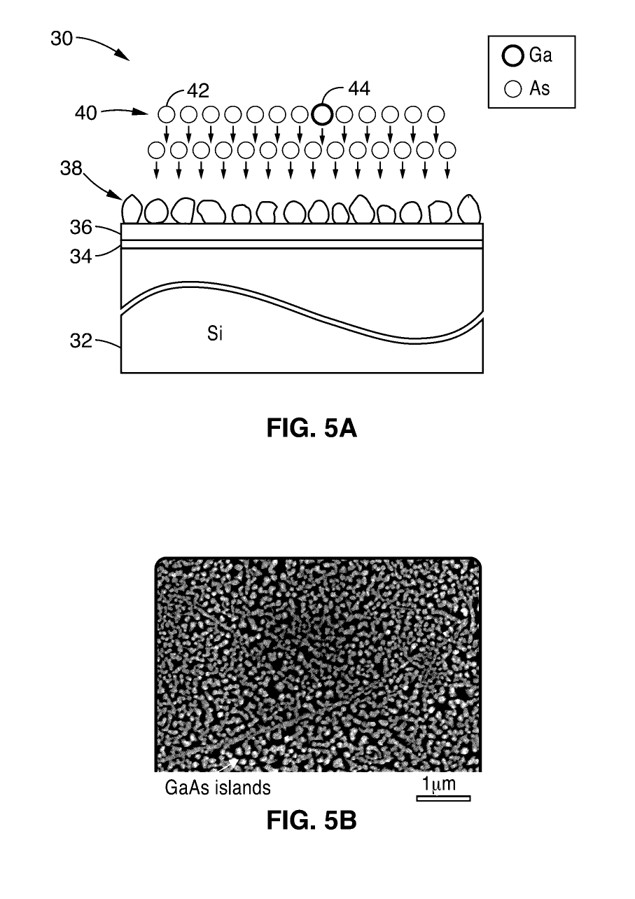

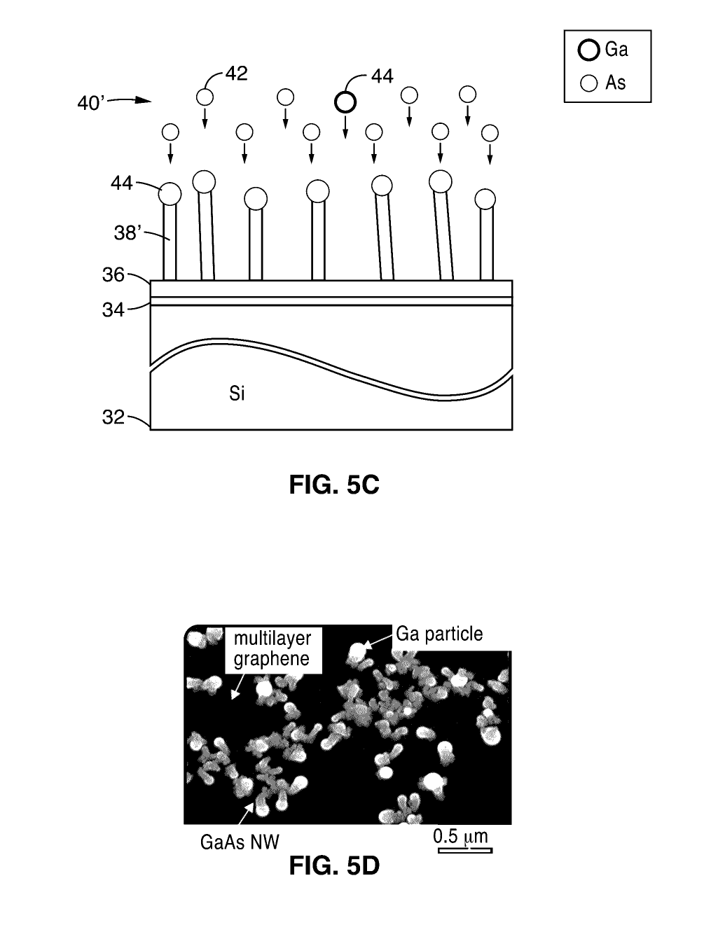

FIG. 5A through FIG. 5D illustrate embodiments 30 comparing Ga growth using graphene. By way of example, an upper portion of an Si substrate 32 is seen over which is a graphene layer 34, then an As prelayer 36 upon which the Ga 38 is to be grown as a flux 40 when As 42 and Ga 44 are received. FIG. 5A depicts a first growth scenario in which a high As flux 40 is received, and from which GaAs islands are primarily formed. FIG. 5B shows a corresponding SEM image of GaAs grown at a V/III ratio of 25 on MLG/Si substrates as depicted in FIG. 5A. According to prior published data, it would still be expected that some grains could be epitaxial with their orientations sensitive to substrate temperature.

To facilitate the nucleation process or a proper (sufficient) anchoring of GaAs atoms on graphene, a second growth was performed with a V/III ratio as low as 10, as depicted 40′ in FIG. 5C. A lower V/III ratio under otherwise the same growth conditions creates Ga droplets 44 on graphene which act as nucleation sites for the formation of GaAs nanorods (NRs) 38′ beside GaAs parasitic crystals, as shown in the SEM image in FIG. 5D. These NRs are present in low density on graphene mainly due to the lack of these Ga droplets. Using a Ga-prelayer (i.e., Ga-terminated surface) followed by such a low V/III ratio and a higher growth temperature would increase the number density of these NRs significantly. The length of the NRs is approximately 100 nm, which is much higher than the nominal thickness of the film.

4.2 GaAs Growth on Ga-Terminated MLG Surface

Since Ga has higher adsorption energy on graphene than As, it is expected that the surface diffusion length of Ga and As on graphene will be reduced and the density of nucleation sites for GaAs growth will be increased. According to our calculations, the surface energy of graphene is increased to 0.43 J m⁻² from 52 mJ m⁻² with the introduction of a Ga-prelayer. Thus, it would be expected that a further reduction of the growth temperature with Ga-prelayer to increase the wettability of the graphene surface could facilitate the nucleation process.

As part of the optimization of the 2D growth of a GaAs nucleation layer on graphene/Si substrates, a range of Ga-prelayer thicknesses was explored. Approximately two monolayers of gallium atop the graphene surface prior to growth yielded the best results in terms of the surface morphology and material quality, as determined by SEM, AFM and Raman data. In fact, use of fewer or more than two monolayers of gallium yields a rough GaAs surface and a low Raman intensity ratio of the LO to TO phonon. It should be noted that such Ga-prelayer deposition was performed at room temperature to achieve a high sticking rate of Ga atoms with graphene, as well as to prevent the Ga clustering observed to occur in higher-temperature depositions. GaAs growth was begun at temperatures as low as 350° C. to avoid islanding and to enhance the nucleation process. This low nucleation layer growth temperature was optimized based on the several growth runs. It should be noted that the growth was performed with a V/III ratio of 25, but the growth rate was varied under these conditions.

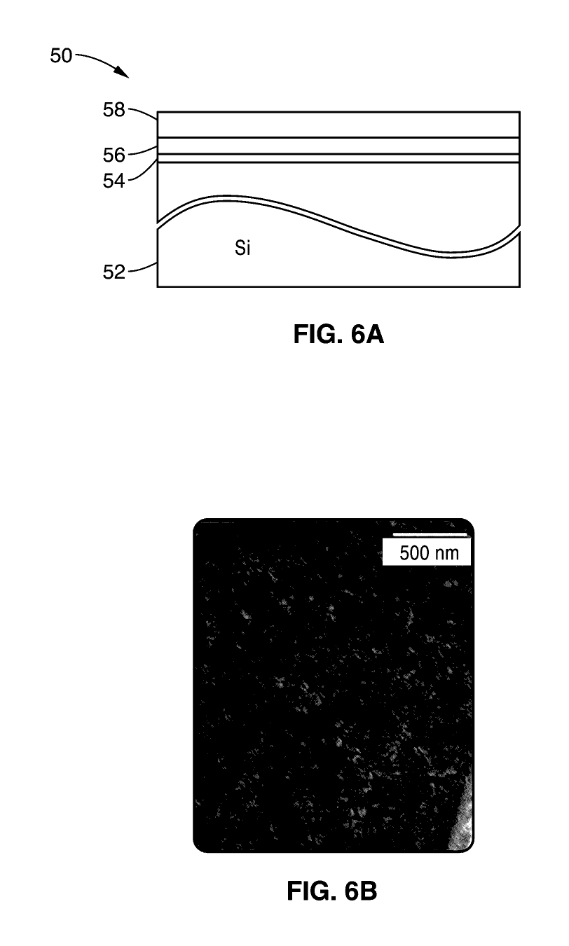

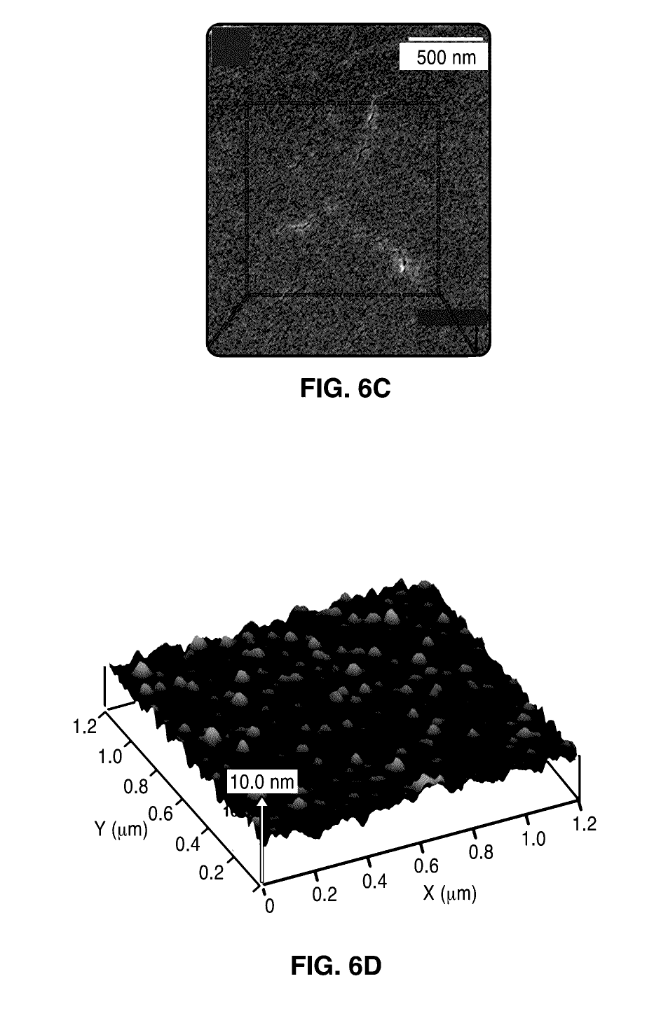

FIG. 6A through FIG. 6D illustrates aspects of a GaAs growth 50 embodiment on a GA terminated MLG surface, shown in FIG. 6A with an Si Substrate 52, a graphene layer 54, a Ga prelayer 56 and a GaAs film layer 58. FIG. 6B depicts an SEM image of GaAs grown on a Ga-terminated MLG surface at growth rate 0.25 Å/s. For the first few layers, GaAs forms widely separated islands around nuclei, and then the islands coalesce as the growth proceeds. The extremely thin Ga-prelayer was observed to have a macroscopic effect on the growth of the GaAs nucleation layer. A comparison of the surface morphology of the structures grown with (FIG. 6B) and without (FIG. 5B) a Ga-prelayer is noticeably different. This marked difference can be attributed to a difference in the wetting angle between MLG and the upper islands enhancing the 2D nature of growth. It should be appreciated that at the initial stage of epitaxy of the GaAs/Si system, a reduction of the wetting angle between the substrate and the overlayer island could be achieved through the use of a Ga-prelayer resulting in a smoother surface morphology. In addition to the effect of Ga-prelayer, the growth rate was also observed to have a significant effect on the surface morphology in 2D-growth-mode. This is demonstrated in FIG. 6C where a lower growth rate of 0.15 Å/s yielded a smoother GaAs surface. Surface RMS roughness as low as 0.6 nm were observed, as seen in FIG. 6D, corresponding to around two monolayers of GaAs, as well as a peak-to-peak height variation of only 3 nm as measured by AFM. This smooth nucleation layer is considered to have an acceptable roughness for subsequent growth of overlayers. To our knowledge, this result is the first illustration of an ultrasmooth morphology for GaAs films on vdW material. This smooth surface could possibly be attributed to a large diffusivity (D) to deposition flux (F) ratio that allows adatoms to reach the surface potential minimum, enhancing a 2D growth of GaAs. In other words, a large value of D/F promotes growth close to an equilibrium condition, allowing the adsorbed species sufficient time to explore the potential energy surface for nucleation so that the system reaches a minimum energy configuration. Hence, the following well-known condition for the step nucleation or layer by layer growth is satisfied by the dimensionless parameter σ

$$σ = \frac{{Fw}^{2} {a}^{2}}{D} < 1 \qquad ( 4 )$$

where a is the in-plane lattice constant of graphene and w is the terrace width of exfoliated MLG.

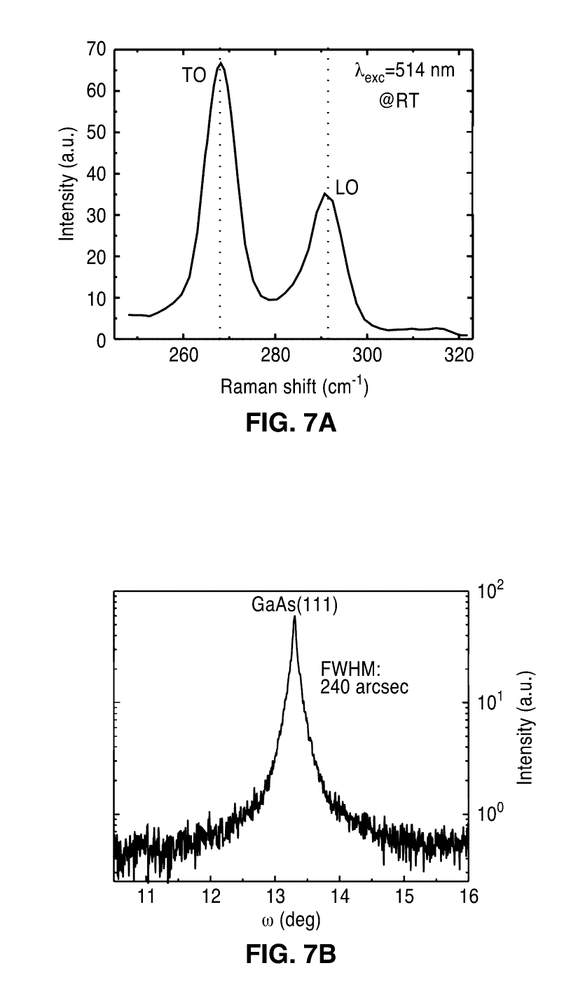

FIG. 7A through FIG. 7B illustrate characterizing crystalline quality and the epitaxial orientation of as-grown GaAs films by Raman spectroscopy in FIG. 7A and x-ray diffraction (XRD) in FIG. 7B. In FIG. 7A are seen the micro-Raman spectrum in which two GaAs Raman signature peaks corresponding to the transverse optic (TO) and longitudinal optic (LO) vibrational bands are located at 268 and 292 cm⁻¹, respectively. The presence of the forbidden but intense TO-mode in the spectrum is a result from the defects in the nucleation layer. The crystallographic quality of such GaAs epilayer was qualitatively evaluated by the ratio of TO and LO intensities (I_{TO}/I_{LO}), which is measured to be as high as 1.8, indicating an incomplete crystallization of the GaAs.

The crystallographic orientation of as-grown GaAs films is mainly defined by the underlying graphene layer, exhibiting triangular lattice symmetry. The Si substrate will have a negligible influence on the orientation of the grown layer. Moreover, the crystalline quality for the thin GaAs film on Ga-terminated graphene was characterized by XRD omega rocking curve scans as displayed in FIG. 7B. These GaAs films are found to have broad rocking curves at Bragg angle. The rocking curve FWHM value for the GaAs(111) plane is as high as 240 arcsec (0.065 deg), indicating that the crystal quality needs to be improved. Despite the poor crystal quality, the low-temperature grown GaAs has a strong (111) oriented fiber-texture. That is clearly an essential step towards epitaxy. A clear correlation between the graphene and the fiber texture is evident which is confirmed by a flat phi-scans for asymmetric (115) peak indicating conclusively fiber-texture.

To assess the quality of the grown film and to benchmark our results, the full width at half maximum (FWHM) of the XRD rocking curve could be compared with the prior reports of FWHM values obtained from GaAs on Si using conventional direct heteroepitaxy. By employing several direct growth approaches, a micron-thick buffer layer was deposited on silicon in order to obtain a FWHM value as low as 242 arcsec. However, the as-grown GaAs film via vdWE achieves the same FWHM with film thicknesses on the order of 25 nm. The two orders of magnitude improvement in the quality of the disclosed GaAs films can be attributed to the graphene buffer layer mitigating lattice and thermal mismatch between GaAs and the underlying substrate.

### 6. Discussion

For the technologically important GaAs/Si heteroepitaxial system, a novel growth concept, QvdWE using graphene as a thermal/lattice mismatch buffer layer has been proposed. This growth mechanism differs from conventional MBE heteroepitaxy due to the use of a 2D buffer material in between the substrate and the overlayers. The buffers have strong bonding within a layer but weak bonding between vdW layers. The disclosure demonstrates how a smooth 2D GaAs thin film can be formed on the MLG/Si system via QvdWE.

This disclosure provides a significant step toward achieving high-quality single crystal GaAs that takes advantage of vdW epitaxy using graphene. The disclosed structure and process can be used to optimize epitaxial thin film growth of other III-V semiconductors, e.g. InP, GaSb on Si using graphene buffer layers. Further optimization of the growth parameters, such as selecting optimum prelayer materials on graphene or the use of other candidate van-der-Waal materials are possible ways to integrate single-crystal 2D GaAs on Si.

From the description herein, it will be appreciated that that the present disclosure encompasses multiple embodiments which include, but are not limited to, the following:

1. A device structure, comprising: a substrate layer; a material layer comprising group III/As; and a van der Waals material buffer layer between the substrate layer and the III/As layer.

2. The device structure of any preceding embodiment, wherein the van der Waals material buffer layer functions as a lattice mismatch/thermal expansion coefficient mismatch relieving buffer layer for the substrate layer and the III/As layer.

3. The device structure of any preceding embodiment, wherein said van der Waals material buffer layer comprises a material selected from a group of van der Waals materials consisting of graphene, hBN, graphene oxide, MoS₂, WS₂, MoSe₂, WSe₂, GaSe, GaTe, In₂Se₃, and Bi₂Se₃.

4. The device structure of any preceding embodiment, wherein said van der Waals material buffer layer is made using a method selected from mechanical exfoliation, transferring vdW material flakes to a surface of the substrate material using a adhesive-tape technique, chemical vapor deposition (CVD), transferring vdW material layer to a surface of the substrate material using a wet transfer technique, to produce vdW material and transfer it into any arbitrary substrate.

5. The device structure of any preceding embodiment, wherein said III/V layer comprises a material selected from a group of III/V compounds consisting of GaAs, InAs, InP, InGaAs, GaSb, InGaSb, AlAs, AlGaAs and GaN.

6. The device structure of any preceding embodiment, wherein said substrate layer comprises a material selected from a group of materials consisting of silicon, SiO₂, silicon-bearing glass, window glass, GaN, Al₂O₃, SiN, BN, and flexible substrates.

7. The device structure of any preceding embodiment, wherein said flexible substrates are transparent.

8. The device structure of any preceding embodiment, wherein said flexible substrates are selected from a group of substrate materials consisting of polyethylene terephthalate (PET), heat-stabilized HS-PET, polyethylene naphthalate (PEN), plastic insulating films, indium tin oxide (ITO)-coated ITO/PEN and ITO/PET transparent conducting films, rigid ITO/glass, FTO/glass substrates, stainless steel and titanium foils.

9. The device structure of any preceding embodiment, wherein said van der Waals material buffer layer comprises one layer of vdW material, multiple-layer vdW material, or multiple layers of multiple-layer vdW material.

10. The device structure of any preceding embodiment, wherein the III/V layer comprises highly textured III/V (111) or III/V having a majority (111) orientation.

11. The device structure as recited in claim 1, wherein the III/V layer comprises a film with a minimum thickness of approximately 25 nm.

12. The device structure of any preceding embodiment, wherein the III/V layer comprises epi, textured with FWHM of 245 arcsec.

13. A method for fabricating a III/V layer on a substrate layer, the method comprising: rinsing a substrate material in a cleaner; acquiring a van der Waals material buffer layer (vdW material) to form a vdW material surface on said substrate; cleaning the substrate material and vdW material surface using a cleaner to remove potential residual organics; degassing the substrate material and vdW surface; and depositing two monolayers of Gallium, Indium, or Aluminum on the vdW surface at room temperature.

14. A method for fabricating a III/V layer on a substrate layer, the method comprising: rinsing a substrate material in a cleaner for a sufficient duration; acquiring a van der Waals material buffer layer (vdW material) to form a vdW material surface on said substrate; cleaning the substrate material and graphene surface using a cleaner to remove potential residual organics; degassing the substrate material and vdW material surface at an elevated temperature for a sufficient duration; and depositing at least two monolayers of a nucleation material, as a prelayer deposition, on the vdW surface at a low temperature.

15. The method of any preceding embodiment, wherein said low temperature, under which at least two monolayers are deposited, comprises room temperature.

16. The method of any preceding embodiment, wherein said prelayer deposition is performed at the low temperature over a sufficient duration; wherein III/V growth is begun at temperatures as low as approximately 350 degrees C.; wherein III/V grown is performed with a V/III ratio of approximately 25; and wherein the III/V growth rate is low with its range on the order of 0.15 Å/s.

17. The method of any preceding embodiment, wherein said prelayer deposition is performed at the low temperature over a sufficient duration.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

TABLE 1
Free surface energies of different materials

| Materials | Surface free energy (mJ/m⁻²) |
|---|---|
| Si (111) | 1467 |
| GaAs (111) | 1697 |
| Graphene | 48 |
| Multi-layer graphene (MLG) | 52 |
| Bismuth selenide (Bi₂Se₃) | 180 |
| Molybdenum selenide (MoS₂) | 46.5 |

What is claimed is:

1. A device structure, comprising:
a substrate layer;
a material layer comprising group III/As; and
a van der Waals material buffer layer between the substrate layer and the III/As layer.

2. The device structure as recited in claim 1, wherein the van der Waals material buffer layer functions as a lattice mismatch/thermal expansion coefficient mismatch relieving buffer layer for the substrate layer and the III/As layer.

3. The device structure as recited in claim 1, wherein said van der Waals material buffer layer comprises a material selected from a group of van der Waals materials consisting of graphene, hBN, graphene oxide, MoS₂, WS₂, MoSe₂, WSe₂, GaSe, GaTe, In₂Se₃, and Bi₂Se₃.

4. The device structure as recited in claim 1, wherein said van der Waals material buffer layer is made using a method selected from mechanical exfoliation, transferring vdW material flakes to a surface of the substrate material using a adhesive-tape technique, chemical vapor deposition (CVD), transferring vdW material layer to a surface of the substrate material using a wet transfer technique, to produce vdW material and transfer it into any arbitrary substrate.

5. The device structure as recited in claim 1, wherein said III/V layer comprises a material selected from a group of III/V compounds consisting of GaAs, InAs, InP, InGaAs, GaSb, InGaSb, AlAs, AlGaAs and GaN.

6. The device structure as recited in claim 1, wherein said substrate layer comprises a material selected from a group of materials consisting of silicon, SiO₂, silicon-bearing glass, window glass, GaN, Al₂O₃, SiN, BN, and flexible substrates.

7. The device structure as recited in claim 6, wherein said flexible substrates are transparent.

8. The device structure as recited in claim 7, wherein said flexible substrates are selected from a group of substrate materials consisting of polyethylene terephthalate (PET), heat-stabilized HS-PET, polyethylene naphthalate (PEN), plastic insulating films, indium tin oxide (ITO)-coated ITO/PEN and ITO/PET transparent conducting films, rigid ITO/glass, FTO/glass substrates, stainless steel and titanium foils.

9. The device structure as recited in claim 1, wherein said van der Waals material buffer layer comprises one layer of vdW material, multiple-layer vdW material, or multiple layers of multiple-layer vdW material.

10. The device structure as recited in claim 1, wherein the III/V layer comprises highly textured III/V (111) or III/V having a majority (111) orientation.

11. The device structure as recited in claim 1, wherein the III/V layer comprises a film with a minimum thickness of approximately 25 nm.

12. The device structure as recited in claim 1, wherein the III/V layer comprises epi, textured with FWHM of 245 arcsec.

13. A method for fabricating a III/V layer on a substrate layer, the method comprising:
rinsing a substrate material in a cleaner;
acquiring a van der Waals material buffer layer (vdW material) to form a vdW material surface on said substrate;
cleaning the substrate material and vdW material surface using a cleaner to remove potential residual organics;
degassing the substrate material and vdW surface; and
depositing two monolayers of Gallium, Indium, or Aluminum on the vdW surface at room temperature.

14. A method for fabricating a III/V layer on a substrate layer, the method comprising:
rinsing a substrate material in a cleaner for a sufficient duration;
acquiring a van der Waals material buffer layer (vdW material) to form a vdW material surface on said substrate;
cleaning the substrate material and graphene surface using a cleaner to remove potential residual organics;
degassing the substrate material and vdW material surface at an elevated temperature for a sufficient duration; and
depositing at least two monolayers of a nucleation material, as a prelayer deposition, on the vdW surface at a low temperature.

15. The method of claim 14, wherein said low temperature, under which at least two monolayers are deposited, comprises room temperature.

16. The method of claim 14:
wherein said prelayer deposition is performed at the low temperature over a sufficient duration;
wherein III/V growth is begun at temperatures as low as approximately 350 degrees C.;
wherein III/V grown is performed with a V/III ratio of approximately 25; and
wherein the III/V growth rate is low with its range on the order of 0.15 Å/s.

17. The method of claim 14, wherein said prelayer deposition is performed at the low temperature over a sufficient duration.
